(19) United States
(12) Patent Application Publication
(10) Pub. No.: US 2021/0182257 A1
(43) Pub. Date: Jun. 17, 2021

(54) METHOD AND SYSTEM TO COMPRESS DECIMAL AND NUMERIC DATA IN DATABASE

(71) Applicant: ALIBABA GROUP HOLDING LIMITED, George Town (KY)

(72) Inventors: Feng ZHENG, San Mateo, CA (US); Ruiping LI, San Mateo, CA (US); Cheng ZHU, San Mateo, CA (US); Congnan LUO, San Mateo, CA (US); Huaizhi LI, San Mateo, CA (US); Xiaowei ZHU, San Mateo, CA (US)

(21) Appl. No.: 16/711,390

(22) Filed: Dec. 11, 2019

(51) Int. Cl. G06F 16/22; G06F 16/28; G06F 16/17; H03M 7/30

(52) U.S. Cl. CPC G06F 16/2237; G06F 16/285; H03M 7/6011; G06F 16/1727; G06F 16/221

(57) ABSTRACT

The present disclosure provides a method for compressing numeric data. The method comprises receiving a data set having a plurality of numeric values; for each numeric value of the plurality of numeric values of the data set, dividing a numeric value into a plurality of arrays arranged according to a specific location of the numeric value, wherein the plurality of arrays include a first array and a second array; grouping, across the plurality of numeric values, first arrays; grouping, across the plurality of numeric values, second arrays; and compressing the group of first arrays and the group of second arrays. The present disclosure also provides a method for decompressing numeric data. The method comprises receiving a data buffer comprising compressed numeric values; decompressing the compressed numeric values into groups of arrays; aligning the groups of arrays according to their relative positions from decimal points; and reconstructing numeric values according to the aligned groups of arrays. In addition, the present disclosure provides database systems and non-transitory computer-readable media for compressing and decompressing numeric data.

### BACKGROUND

Decimal and numeric values are types of data that are very common in modern databases. Many companies have developed database compression and decompression methods to allow for more efficient storing of large amounts of data. While some compression techniques can improve an overall efficiency of storing decimal and numeric data, they all have their drawbacks. For example, some techniques require that a range of values be explicitly specified. Additionally, some techniques focus on compressing decimal and numeric values on individual bases rather than finding patterns in all decimal and numeric values. Furthermore, some techniques can only compress decimal and numeric values into fixed-length formats.

### SUMMARY

Embodiments of the present disclosure provides a method for compressing numeric data. The method comprises receiving a data set having a plurality of numeric values; for each numeric value of the plurality of numeric values of the data set, dividing a numeric value into a plurality of arrays arranged according to a specific location of the numeric value, wherein the plurality of arrays include a first array and a second array; grouping, across the plurality of numeric values, first arrays; grouping, across the plurality of numeric values, second arrays; and compressing the group of first arrays and the group of second arrays.

Embodiments of the present disclosure also provides a method for decompressing numeric data. The method comprises receiving a data buffer comprising compressed numeric values; decompressing the compressed numeric values into groups of arrays; aligning the groups of arrays according to their relative positions from a specific location; and reconstructing numeric values according to the aligned groups of arrays.

Moreover, embodiments of the present disclosure provide database systems for compressing numeric data. The database system comprises a memory and a processor configured to compress numeric data by receiving a data set having a plurality of numeric values; for each numeric value of the plurality of numeric values of the data set, dividing a numeric value into a plurality of arrays arranged according to a specific location of the numeric value, wherein the plurality of arrays include a first array and a second array; grouping, across the plurality of numeric values, first arrays; grouping, across the plurality of numeric values, second arrays; and compressing the group of first arrays and the group of second arrays.

Moreover, embodiments of the present disclosure provide database systems for decompressing numeric data. The database system comprises a memory and a processor configured to decompress numeric data by receiving a data buffer comprising compressed numeric values; decompressing the compressed numeric values into groups of arrays; aligning the groups of arrays according to their relative positions from a specific location; and reconstructing numeric values according to the aligned groups of arrays.

Moreover, embodiments of the present disclosure also provide non-transitory computer readable media that store a set of instructions that are executable by one or more processors of an apparatus to perform a method for compressing in a database environment. The method comprises receiving a data set having a plurality of numeric values; for each numeric value of the plurality of numeric values of the data set, dividing a numeric value into a plurality of arrays arranged according to a specific location of the numeric value, wherein the plurality of arrays include a first array and a second array; grouping, across the plurality of numeric values, first arrays; grouping, across the plurality of numeric values, second arrays; and compressing the group of first arrays and the group of second arrays.

embodiments of the present disclosure also provide non-transitory computer readable media that store a set of instructions that are executable by one or more processors of an apparatus to perform a method for decompressing in a database environment. The method comprises receiving a data buffer comprising compressed numeric values; decompressing the compressed numeric values into groups of arrays; aligning the groups of arrays according to their relative positions from a specific location; and reconstructing numeric values according to the aligned groups of arrays.

### BRIEF DESCRIPTION OF THE DRAWINGS

The accompanying drawings, which are incorporated in and constitute a part of this specification, illustrate embodiments consistent with the invention and, together with the description, explain the principles of the invention.

FIG. 1 illustrates exemplary methods of storing numeric types of data in a database.

FIG. 2 illustrates a schematic diagram of an exemplary server of a database, according to some embodiments of the present disclosure.

FIG. 3 illustrates an exemplary diagram illustrating data compression using vertical alignment of numeric data, according to some embodiments of the present disclosure.

FIG. 4 illustrates an exemplary diagram illustrating data decompression using vertical alignment of numeric data, according to some embodiments of the present disclosure.

FIG. 5 illustrates a flowchart of an exemplary method for compressing numeric data based on vertical alignment in a database, according to some embodiments of the disclosure.

FIG. 6 illustrates a flowchart of an exemplary method for compressing numeric data having headers based on vertical alignment in a database, according to some embodiments of the disclosure.

FIG. 7 illustrates a flowchart of an exemplary method for compressing numeric data arranged in chunks based on vertical alignment in a database, according to some embodiments of the disclosure.

FIG. 8 illustrates a flowchart of an exemplary method for decompressing numeric data based on vertical alignment in a database, according to some embodiments of the disclosure.

FIG. 9 illustrates a flowchart of an exemplary method for decompressing numeric data having headers based on vertical alignment in a database, according to some embodiments of the disclosure.

FIG. 10 illustrates a flowchart of an exemplary method for decompressing numeric data arranged in chunks based on vertical alignment in a database, according to some embodiments of the disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the invention. Instead, they are merely examples of apparatuses and methods consistent with aspects related to the invention as recited in the appended claims.

Many of the modern databases allow for specifying data types. For example, many databases support decimal and numeric data types. The databases can support these data types by allowing users to specify a column of a table to be of decimal or numeric types.

The decimal and numeric types store exact numeric values. These types are used when it is important to preserve precision, such as monetary data. In practice, the decimal and numeric data types are widely used in database applications. A decimal or numeric type can be defined with two parameters: precision and scale. Precision is a maximum number of digits. Scale is a number of digits to the right of the decimal point. For example, 1234.56 has a precision of 6 and a scale of 2. In many databases, decimal and numeric types are used as the same type, and they are implemented in the same manner. In the following description, decimal types and numeric types will be used interchangeably.

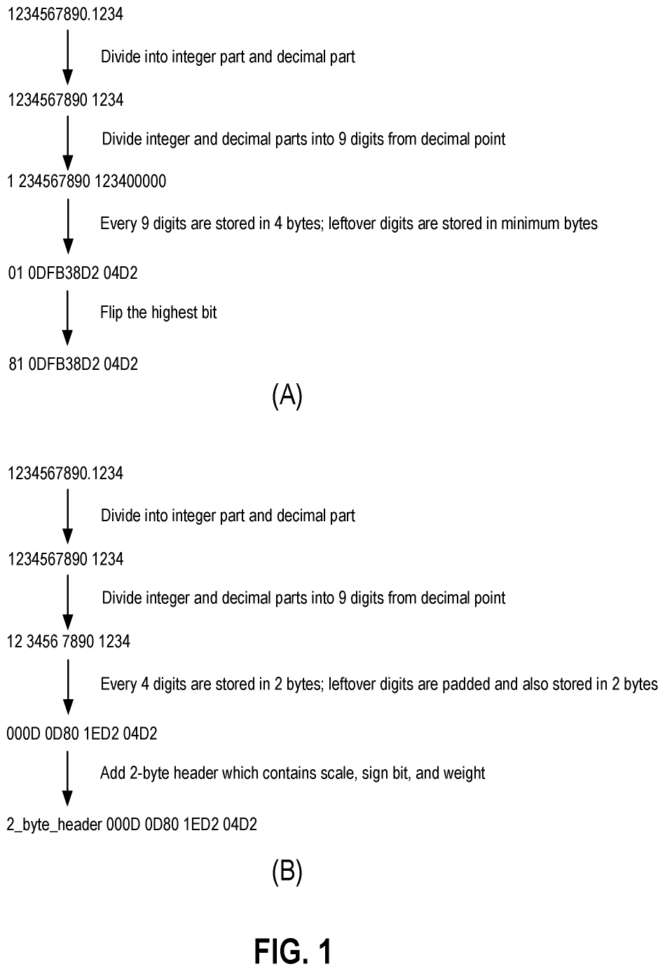

Databases use different methods to store numeric types of data. FIG. 1 illustrates exemplary methods of storing numeric types of data in a database. Some databases store numeric types of data by grouping every 9 digits of a decimal number in 4 bytes. As shown in FIG. 1(A), a decimal number 1234567890.1234 is stored into a database. The database divides the decimal number into its integer part and decimal part, and then divides the integer and the decimal parts of the decimal number into groups of 9 digits from the decimal point, which results in “1 234567890 1234000000.” Every group of 9 digits are then stored in 4 bytes, and the leftover digits are stored in minimum bytes. Sometimes, the leftover digits are padded with zeros and stored in 4 bytes. As a result, the decimal number becomes “01 0DFB38D2 04D2.” In the end, the highest bit is flipped, and the decimal number is stored in the database as “81 0DFB38D2 04D2.”

Some databases store numeric types of data by grouping every 4 digits into 2 bytes. As shown in FIG. 1(B), a decimal number “1234567890.1234” is divided into an integer part and a decimal part. The integer part and the decimal part are then divided into groups of 4 digits from the decimal point, which results in “12 3456 7890 1234.” Every group of 4 digits are stored in 2 bytes, and leftover digits are padded and also stored in 2 bytes. As a result, the decimal number becomes “000D 0D80 1ED2 04D2.” In the end, a 2-byte header is added that may contain scale, sign bit, or weight information, and the decimal number is stored in the database as “2_byte_header 000D 0D80 1ED2 04D2.”

As shown in FIG. 1(A) and FIG. 1(B), different databases tend to store numeric types of data using different methods and standards. In addition, it is common to pack multiple digits into fixed-sized bytes (e.g., packing every 9 digits into 4 bytes, packing every 4 digits into 2 bytes, etc.).

Databases can compress a set of numeric values to save storage space and input/output (“I/O”) cost. For example, many of the modern databases are columnar databases, which store data in columns rather than in rows. Columnar databases can achieve better compression since data in a column is often of a same type (e.g., the numeric type). In addition, numeric types of data in a single column tend to be similar to each other. In a columnar database, all values of the same column can be stored and compressed together.

In addition to columnar databases, many of the modern databases adopt a row-group columnar storage or row-column hybrid storage. It first divides rows into row groups. The column-oriented storage is then used for each row group.

From an end-to-end performance perspective, a compression method for numeric types of data should have the following features. First, the compression method should be lossless. In other words, the compression method should not cause any loss of information or precision when compressed data is compared with original data. Second, the compression method should have a high compression ratio. The compression ratio is defined as the ratio between a size of the original data versus a size of the compressed data. A higher compression ratio indicates more savings in storage and I/O cost. Third, the compression method should feature a high compression speed. The compression speed can be measured as the amount of data that is compressed in a unit of time. A higher compression speed indicates a faster write and ingestion performance. Fourth, the compression method should feature a higher decompression speed. The decompression speed is measured as the amount of data that is decompressed in a unit of time. A higher decompression speed indicates faster read and query performance.

Some databases compress a column of numeric type of data into a fixed-length format. For example, the fixed length is determined by a range of values for the numeric data, and the fixed length is not stored with the values. In these databases, the range of values must be explicitly specified in the database system, which makes the compression less flexible. In addition, some compression techniques focus on compressing decimal and numeric values on an individual basis. These compression techniques often fail to account for the patterns and similarities among numeric values in a column, which has the potential to provide the compression method a higher compression ratio. In addition, some patterns among the numeric values in a column may not be detectable unless the numeric values are divided into arrays of digits. There is a need to develop a new technique that can provide a much more flexible compression format that can achieve higher compression ratio without adding strains to compression/decompression speed.

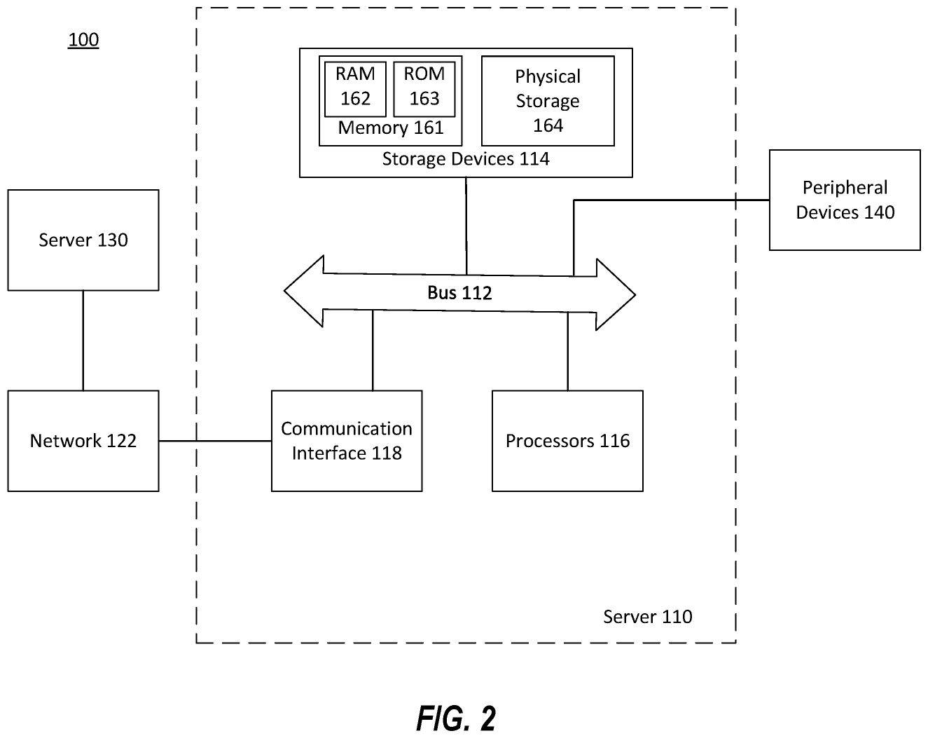

Embodiments of the present disclosure resolve these issues by providing systems and methods for compressing numeric data in a database. FIG. 2 illustrates a schematic diagram of an exemplary server of a database, according to some embodiments of the present disclosure. According to FIG. 2, server 110 of database 100 comprises a bus 112 or other communication mechanism for communicating information, and one or more processors 116 communicatively coupled with bus 112 for processing information. Processors 116 can be, for example, one or more microprocessors. In some embodiments, database 100 can be an online analytical processing (“OLAP”) database.

Server 110 can transmit data to or communicate with another server 130 through a network 122. Network 122 can be a local network, an internet service provider, internet, or any combination thereof. Communication interface 118 of server 110 is connected to network 122. In addition, server 110 can be coupled via bus 112 to peripheral devices 140, which comprises displays (e.g., cathode ray tube (CRT), liquid crystal display (LCD), touch screen, etc.) and input devices (e.g., keyboard, mouse, soft keypad, etc.).

Server 110 can be implemented using customized hard-wired logic, one or more ASICs or FPGAs, firmware, or program logic that in combination with the server causes server 110 to be a special-purpose machine.

Server 110 further comprises storage devices 114, which may include memory 161 and physical storage 164 (e.g., hard drive, solid-state drive, etc.). Memory 161 may include random access memory (RAM) 162 and read only memory (ROM) 163. Storage devices 114 can be communicatively coupled with processors 116 via bus 112. Storage devices 114 may include a main memory, which can be used for storing temporary variables or other intermediate information during execution of instructions to be executed by processors 116. Such instructions, after being stored in non-transitory storage media accessible to processors 116, render server 110 into a special-purpose machine that is customized to perform operations specified in the instructions. The term “non-transitory media” as used herein refers to any non-transitory media storing data or instructions that cause a machine to operate in a specific fashion. Such non-transitory media can comprise non-volatile media or volatile media. Non-transitory media include, for example, optical or magnetic disks, dynamic memory, a floppy disk, a flexible disk, hard disk, solid state drive, magnetic tape, or any other magnetic data storage medium, a CD-ROM, any other optical data storage medium, any physical medium with patterns of holes, a RAM, a PROM, and EPROM, a FLASH-EPROM, NVRAM, flash memory, register, cache, any other memory chip or cartridge, and networked versions of the same.

Various forms of media can be involved in carrying one or more sequences of one or more instructions to processors 116 for execution. For example, the instructions can initially be carried out on a magnetic disk or solid-state drive of a remote computer. The remote computer can load the instructions into its dynamic memory and send the instructions over a telephone line using a modem. A modem local to server 110 can receive the data on the telephone line and use an infra-red transmitter to convert the data to an infra-red signal. An infra-red detector can receive the data carried in the infra-red signal and appropriate circuitry can place the data on bus 112. Bus 112 carries the data to the main memory within storage devices 114, from which processors 116 retrieves and executes the instructions.

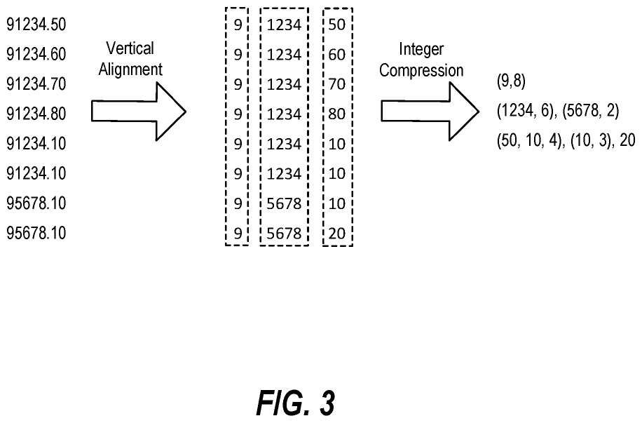

Embodiments of the present disclosure provide a method to compress columns of numeric values in an efficient manner. FIG. 3 illustrates an exemplary diagram illustrating data compression using vertical alignment of numeric data, according to some embodiments of the present disclosure. It is appreciated that data compression shown in FIG. 3 may be performed by server 110 of FIG. 2.

As shown in FIG. 3, there is a column of 8 numeric values to compress. These numeric values can represent, for example, pricings of a product in different stores. Each of the numeric values is first divided into an array of 4 digits from the decimal point. For example, numeric value “91234.50” is divided into three arrays of digits from the decimal point: “9,” “1234,” and “50.” Every array of 4 digits can then be viewed as a 2-byte integer. These integers from all the numeric values are then aligned vertically according to their relative position from the decimal point. For example, the array of digits “1234” from numeric value “91234.50” is aligned with an array of digits “5678” from numeric value “95678.10,” because “1234” and “5678” are both the first array of digits to the left of the decimal point. Similarly, the array of digits “50” from numeric value “91234.50” is aligned with an array of digits “60” from numeric value “91234.60” because they are both the first array of digits to the right of the decimal point.

After the arrays of digits are aligned vertically, each vertically aligned array of digits are grouped together into a column, and each column is compressed separately. For example, as shown in FIG. 3, the first column of the arrays of digits comprises 8 arrays of digit “9.” When the first column is compressed, the first column becomes “(9, 8),” representing 8 counts of digit “9.” The second column comprises 6 arrays of digits “1234” and 2 arrays of digits “5678.” When the second column is compressed, the second column becomes “(1234, 6), (5678, 2),” which represents 6 counts of digits “1234” followed by 2 counts of digits “5678.” The third column comprises arrays of digits “50,” “60,” “70,” “80,” “10,” “10,” “10,” and “20.” When the third column is compressed, the third column becomes “(50, 10, 4), (10, 3), 20,” which represents an arithmetic sequence starting at 50 with a common difference of 10 and a count of 4, followed 3 counts of digits “10,” and a single count of digits “20.”

The data compression shown in FIG. 3 takes advantage of local patterns and similarities among arrays of digits that are grouped into a same column. Viewing the 8 uncompressed values together, they do not appear to possess enough similarity or patterning for any existing compression technique to fully take advantages of. However, when each of the numeric values is divided into arrays of 4 digits from the decimal point, the arrays that are vertically aligned and grouped together start to possess strong similarities and patterning. For example, the first column of arrays is simply 8 counts of array “9,” and the second column of arrays can be easily represented by “(1234, 6), (5678, 2)” after compression. This local patterning and similarity among numeric values are prevalent in databases, regardless of what the numeric values represent. For example, the numeric values shown in FIG. 3 can represent pricings a product in different stores. It is reasonable to assume that the higher digits in the pricings tend to be similar, whereas the fluctuations and differences in pricing tend to concentrate in the lower digits and the decimal parts of the pricings. As a result, the data compression shown in FIG. 3 can achieve a higher compression ratio, hence allowing the database to save storage space and input/output (“I/O”) cost. Moreover, although the data compression shown in FIG. 3 tends to process more columns than conventional data compression techniques, arrays in each column are smaller in size. As a result, the data compression shown in FIG. 3 does not add much strain to compression speed.

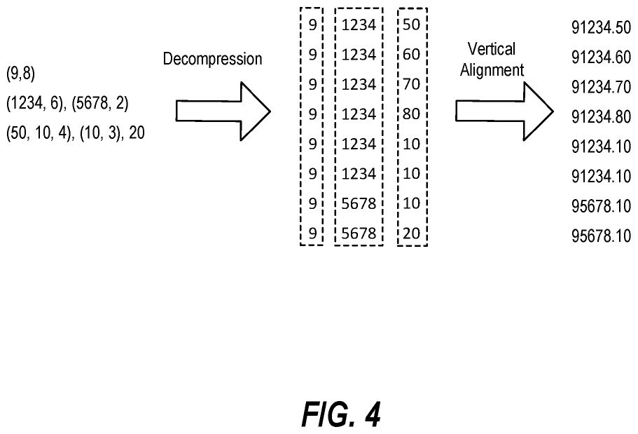

Embodiments of the present disclosure further provide a method to decompress columns of numeric values in an efficient manner. FIG. 4 illustrates an exemplary diagram illustrating data decompression using vertical alignment of numeric data, according to some embodiments of the present disclosure. It is appreciated that data compression shown in FIG. 3 may be performed by server 110 of FIG. 2.

As shown in FIG. 4, the compressed data is first decompressed into three columns of arrays. The decompression technique corresponds to the compression technique that was used to generate the compressed data. For example, the decompression technique can correspond to certain integer compression techniques, such as run-length encoding (RLE), delta compression, bit-packing compression, pFOR compression, etc. After the compressed data is decompressed, three columns of arrays are generated, namely a first column of 8 counts of array “9,” a second column of 6 counts of array “1234” and 2 counts of array “5678,” and a third column of arrays “50,” “60,” “70,” “80,” “10,” “10,” “10,” and “20.” These three columns are then vertically aligned according to their relative positions from decimal points. As a result, the original numeric values are reconstructed.

In some embodiments, the database can internally store a header for some or all of the numeric values. For example, as shown in FIG. 1(B), there can be a 2-byte header that may contain scale, sign bit, weight information, etc. These headers can also be vertically aligned to form a column. As a result, the column comprising these headers can be compressed together using the same method as other arrays of digits (e.g., compression of the first column in FIG. 3). In addition, the column comprising these headers can be decompressed together using the same method as other arrays of digits (e.g., decompression of the first column in FIG. 4).

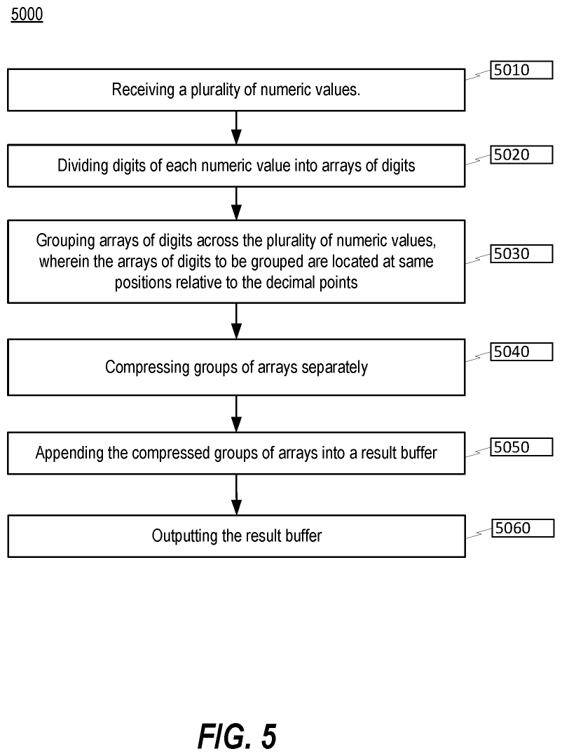

FIG. 5 illustrates a flowchart of an exemplary method for compressing numeric data based on vertical alignment in a database, according to some embodiments of the disclosure. It is appreciated that method 5000 of FIG. 5 may be performed by server 110 of FIG. 2. It is also appreciated that method 5000 of FIG. 5 may be performed on a columnar database or a row-column hybrid database.

In step 5010, a data set comprising a plurality of numeric values is received. In some embodiments, the data set is stored in a database storage (e.g., storage devices 114 of FIG. 2). In some embodiments, the data set may be received from another database server (e.g., server 130 of FIG. 2).

In step 5020, each numeric value from the plurality of numeric values is divided into arrays of digits. In some embodiments, the arrays of digits are created according to their relative positions to a specific location of the numeric value. In some embodiments, the specific location is the decimal point of the numeric value. For example, as shown in FIG. 3, digits “1234” are grouped into an array because they are closest to the decimal point of the numeric value “91234.50.” The next closest digit “9” is grouped into a different array.

In some embodiments, the size of an array of digits is fixed, and the size is represented by an array size parameter. In some embodiments, the array size parameter can be defined by a user of the database system. For example, a user may define the array size parameter to be 4, and each numeric value is divided into arrays of 4 digits (e.g., numeric value “91234.50” of FIG. 3). In some embodiments, the array size parameter can be defined by the database system according to the database system's analysis of compression efficiency, and the array size parameter is stored in the database's storage (e.g., storages devices 114 of FIG. 2). In some embodiments, the array size parameter can be defined according to the number systems of the data in order to maximize the compression efficiency for the particular type of the number system. For example, an array size parameter for binary numbers may be defined differently from an array size parameter for decimal numbers.

In some embodiments, some arrays of digits located at both ends of a numeric value are not enough to fill the size defined by the array size parameter. For example, as shown in FIG. 3, digit “9” forms an array by itself, even though the array ends up with less than 4 digits. These arrays are padded with zeros to fill up the size defined by the array size parameter. For example, digit “9” can be padded with three zeros to form an array “0009.” In some embodiments, if the array comprises leading digits in an integer part of a numeric value, the array is padded with zeros at the front. In some embodiments, if the array comprises tailing digits in a fractional part of the numeric value, the array is padded with zeros at the end. For example, digits “50” from numeric value “91234.50” can be padded with 2 zeros at the end to form an array “5000.” In some embodiments, arrays that comprises tailing digits in a decimal part of a numeric value is not padded with zeros. In some embodiments, the arrays are converted into binary values first before they are padded with zeros. For example, as shown in FIG. 1(B), the left most array “12” is converted to “D” before it is padded with zeros to form a 2-byte binary array “000D.”

In some embodiments, the number of arrays from an integer part of the numeric values can be determined based on the following formula:

$${N}_{i n t} = c e i l ( \frac{( precision - scale )}{array size parameter} ) ,$$

where precision is a maximum number of digits in the numeric value, scale is a number of digits to the right of the decimal point, and array size parameter is a size of an array of digits. ceil( ) is a ceiling function, which returns a maximum value out of all the numeric values, and Nᵢₙₜ is the number of arrays on the integer part of the numeric values. The ceiling function ceil( ) can be used in scenarios where different numeric values may have different number of arrays in their integer parts. For example, if the array size parameter is 4, numeric value “91234” may be divided into 2 arrays, whereas numeric value “912348765” may be divided into 3 arrays. The ceiling function ceil( ) would return 3 for these two numeric values for the number of arrays parameter Nᵢₙₜ. In some embodiments, numeric values that end up with less arrays than the number of arrays parameter Nᵢₙₜ is padded with arrays of zeros. For example, numeric values “91234” may be divided into arrays “0000,” “0009,” and “1234.”

In some embodiments, the number of arrays on a decimal part of the numeric values can be determined based on the following formula:

$${N}_{d e c} = c e i l ( \frac{scale}{array size parameter} ) ,$$

where scale is a number of digits to the right of the decimal point, and array size parameter is a size of an array of digits. ceil( ) is a ceiling function, which returns a maximum value out of all the numeric values, and N_{dec} is the number of arrays on the decimal part of the numeric values. The ceiling function ceil( ) can be used in scenarios where different numeric values may have different number of arrays in their decimal parts. For example, if the array size parameter is 4, numeric value “0.12345” may be divided into 2 arrays from the decimal part, whereas numeric value “0.123456789” may be divided into 3 arrays from the decimal part. The ceiling function ceil( ) would return 3 for these two numeric values for the number of arrays parameter N_{dec}. In some embodiments, numeric values that end up with less arrays than the number of arrays parameter N_{dec} is padded with arrays of zeros. For example, numeric values “0.12345” may be divided into arrays “1234,” “5000,” and “0000” from its decimal part.

Referring back to FIG. 5, in step 5030, arrays of digits that are located at same positions relative to the decimal points are grouped together. In some embodiments, starting from the right most (lowest) array in the integer part of a numeric value, a first array of digits is taken from each numeric value, and these first arrays of digits across the plurality of numeric values are grouped together. The second arrays of digits are also grouped together until there are no more arrays to group in any numeric values. For example, as shown in FIG. 3, starting from the right most array in the integer part of numeric value “91234.50,” a first array of digits is “1234.” These first arrays of digits across the numeric values are grouped together, forming a column of 6 counts of array “1234” followed by 2 counts of array “5678.” The second array of digits is “9,” and these second arrays are grouped together to form a column that has 8 counts of arrays “9.”

The decimal part of the numeric values can be grouped similarly. For example, starting from the left most (highest) array in the fractional part of a numeric value, a first array of digits is taken from each numeric value, and these first arrays of digits across the plurality of numeric values are grouped. The second arrays of digits are also grouped together until there are no more arrays to group in any numeric values. For example, as shown in FIG. 3, starting from the left most array in the decimal part of numeric value “91234,50,” a first array of digits is “50.” These first arrays of digits are grouped together, forming a column of arrays “50,” “60,” “70,” “80,” “10” “10,” “10,” and “20.”

In step 5040, some or all groups of arrays are compressed separately. For example, as shown in FIG. 3, the first column of array is compressed to “(9, 8).” In some embodiments, integer compression techniques such as RLE, delta compression, bit-packing compression, pFOR compression, etc. can be used during the compression of the groups of arrays.

In step 5050, the compressed groups of arrays are appended into a result buffer. In some embodiments, the result buffer is an output of method 5000. In some embodiments, the result buffer is reset before step 5010 or step 5020, making the result buffer available for a new round of compression.

In step 5060, the result buffer is outputted. In some embodiments, the result buffer is stored into a storage (e.g., storage devices 114 or physical storage 164 of FIG. 2). In some embodiments, the result buffer is outputted to another database server (e.g., server 130 of FIG. 2).

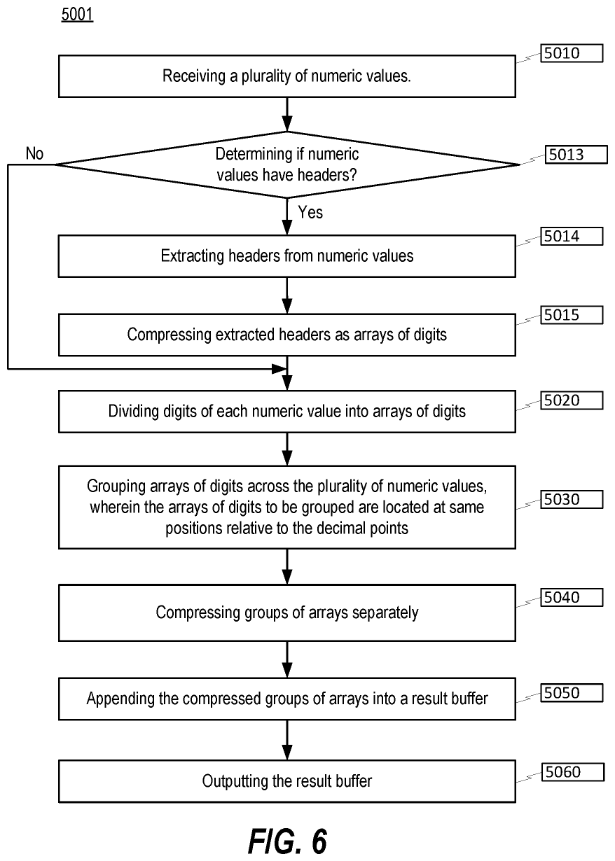

In some embodiments, the database can internally store a header for some or all of the numeric values. FIG. 6 illustrates a flowchart of an exemplary method for compressing numeric data having headers based on vertical alignment in a database, according to some embodiments of the disclosure. On the basis of FIG. 5, method 5001 of FIG. 6 further comprises steps 5013, 5014, and 5015. It is appreciated that method 5001 of FIG. 5 may be performed by server 110 of FIG. 2.

In step 5013, it is determined whether the plurality of numeric values have headers. In some embodiments, the database system reads some or all of the plurality of numeric values and determines whether they have headers. If it is determined that the numeric values have headers, step 5014 and 5015 are executed. If it is determined that the numeric values do not have headers, step 5020 is executed.

In step 5014, headers are extracted from the plurality of numeric values. For example, as shown in FIG. 1(B), a numeric value may be represented as “2_byte_header 000D 0D80 1ED2 04D2.” The “2_byte_header” is extracted from the original numeric value. In some embodiments, headers are located at the beginning of the numeric values. The locations of headers in a numeric value is referred to as header's locations.

In step 5015, the headers are compressed together. In some embodiments, the headers are treated as an array of numeric values. As a result, the headers can be compressed using the same compression technique as the other numeric values. In some embodiments, the compressed headers are appended to the result buffer.

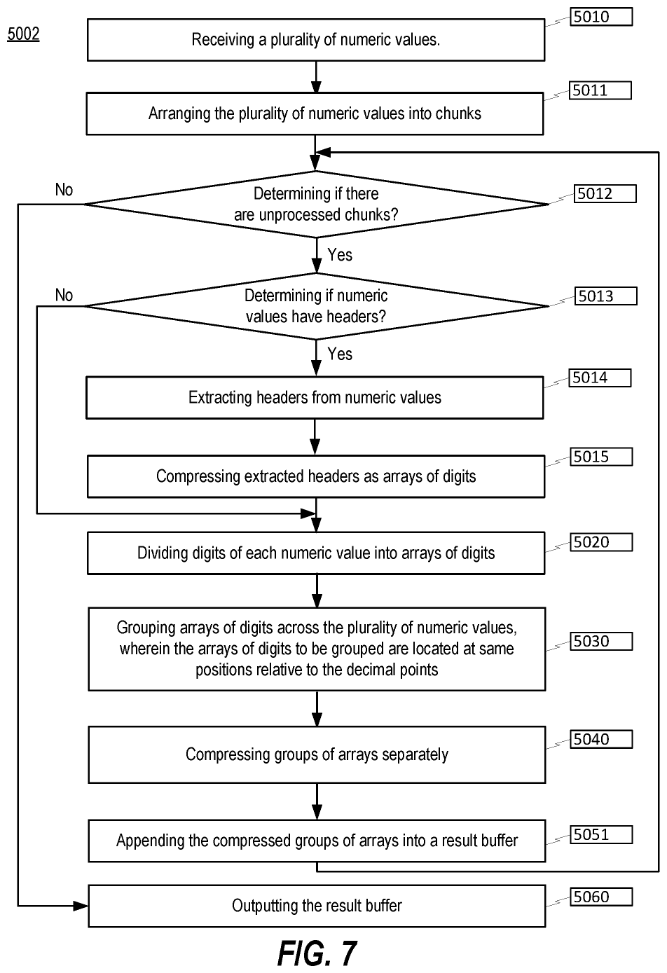

In some embodiments, the plurality of numeric values can be processed in units of chunks. In other words, the plurality of numeric values can be divided into a plurality of chunks, and each chunk of numeric values can be processed separately. FIG. 7 illustrates a flowchart of an exemplary method for compressing numeric data arranged in chunks based on vertical alignment in a database, according to some embodiments of the disclosure. On the basis of FIG. 6, method 5002 of FIG. 7 further comprises steps 5011, 5012, and 5051. It is appreciated that method 5002 of FIG. 7 may be performed by server 110 of FIG. 2.

In step 5011, the plurality of numeric values are arranged into chunks. In some embodiments, a chunk size parameter is used to keep track of a number of numeric values in a chunk. In some embodiments, the chunk size parameter has a default value of 512. For example, if the plurality of numeric values comprises 1224 numeric values in total, the plurality of numeric values is divided or grouped into three chunks. The first two chunks has 512 numeric values each, and the third chunk has the remaining 200 values.

In step 5012, it is determined whether there are chunks of numeric values that are not processed. If there are chunks that are not processed, a chunk of numeric values is sent to step 5013 for processing. If there are no more chunks to be processed, step 5060 is executed. As a result, the numeric values are processed in units of chunks.

In step 5051, the compressed groups of arrays are appended into a result buffer. Unlike step 5050 of FIG. 5 and FIG. 6, the result buffer from step 5051 may not be the output of method 5002. Instead, step 5012 is executed after step 5051 to determine if there are chunks of numeric values that are not processed.

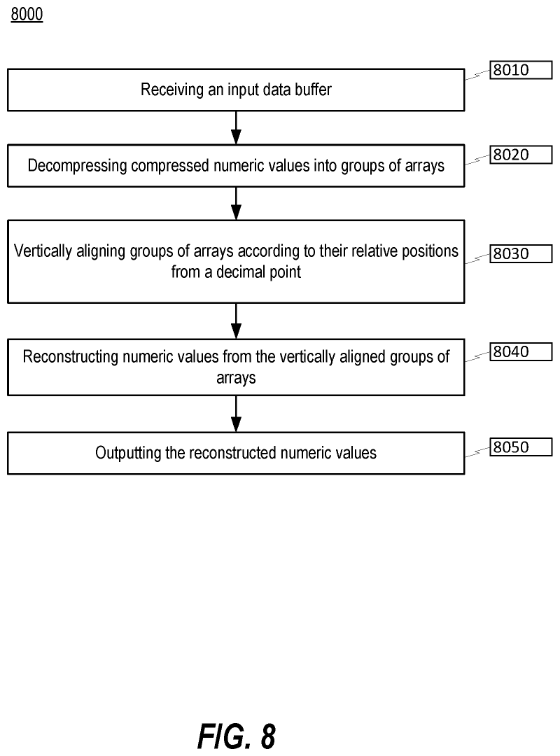

Embodiments of the present disclosure further provide a method to decompress numeric data based on vertical alignment in a database. FIG. 8 illustrates a flowchart of an exemplary method for decompressing numeric data based on vertical alignment in a database, according to some embodiments of the disclosure. It is appreciated that method 8000 of FIG. 8 may be performed by server 110 of FIG. 2. It is also appreciated that method 8000 of FIG. 8 may be performed on a columnar database or a row-column hybrid database.

In step 8010, an input data buffer containing compressed numeric values is received. In some embodiments, the input data buffer is stored in a database storage (e.g., storage devices 114 of FIG. 2). In some embodiments, the input data buffer may be received from another database server (e.g., server 130 of FIG. 2).

In step 8020, compressed numeric values are decompressed into groups of arrays. In some embodiments, the decompression process uses decompression methods that are associated with the compression method used in the compression process. The decompression process can use decompression methods associated with integer compression techniques such as RLE, delta compression, bit-packing compression, pFOR compression, etc. For example, as shown in FIG. 4, compressed numeric values “(9, 8)” can be decompressed into a column of 8 counts of array “9,” and compressed numeric values “(1234, 6), (5578, 2)” can be decompressed into a column of 6 counts of array “1234” and 2 counts of array “5678.” This decompression can continue until all groups of arrays have been processed (e.g., decompressed arrays of FIG. 4).

In step 8030, groups of arrays are aligned vertically according to their relative positions from a specific location. In some embodiments, the specific location is a decimal point. In some embodiments, the relative position of each group of arrays can be determined or calculated according to their location in the input data buffer. For example, a compression method of FIG. 5, FIG. 6, or FIG. 7 may choose to append groups of arrays that are closer to the decimal point first before appending groups of arrays that are further from the decimal point. As a result, when a decompression method corresponding to the compression method decompresses the input data buffer, the first groups of arrays to be decompressed in the input data buffer can be determined to be further from the decimal point. For example, as shown in FIG. 4, compressed numeric values “(9, 8)” is appended to the top of the input data buffer because it is the furthest group of array from the decimal point in the integer part of the numeric values. Therefore, after compressed numeric values “(9, 8)” is decompressed, the column of 8 counts of array “9” is aligned to the most left position, because numeric values “(9, 8)” was read off the top of the input data buffer.

In some embodiments, the number of arrays on an integer part of the numeric values can be determined based on the following formula:

$${N}_{i n t} = c e i l ( \frac{( precision - scale )}{array size parameter} ) ,$$

where precision is a maximum number of digits in the numeric value, scale is a number of digits to the right of the decimal point, and array size parameter is a size of an array of digits. ceil( ) is a ceiling function, which returns a maximum value out of all the numeric values, and Nᵢₙₜ is the number of arrays on the integer part of the numeric values. Since the number of arrays on an integer part of the numeric values can be determined or calculated, the decompression method can obtain information on how many groups of arrays to decompress in the input data buffer.

In some embodiments, the number of arrays on a decimal part of the numeric values can be determined based on the following formula:

$${N}_{d e c} = c e i l ( \frac{scale}{array size parameter} ) ,$$

where scale is a number of digits to the right of the decimal point, and array size parameter is a size of an array of digits. ceil( ) is a ceiling function, which returns a maximum value out of all the numeric values, and N_{dec} is the number of arrays on the decimal part of the numeric values. Since the number of arrays on the decimal part of the numeric values can be determined or calculated, the decompression method can obtain information on how many groups of arrays to decompress in the input data buffer.

Referring back to FIG. 8, in step 8040, each numeric value is reconstructed from the vertically aligned groups of arrays. In some embodiments, the numeric values are reconstructed by combining the aligned arrays of digits into a numeric value and adding a decimal point according to the relative positions of the aligned groups of arrays. For example, as shown in FIG. 4, arrays “9,” “1234,” and “50” are combined, and a decimal point is added to form the numeric value “91234.50.”

In step 8050, the reconstructed numeric values are outputted. In some embodiments, the reconstructed numeric values are stored into a storage (e.g., storage devices 114 or physical storage 164 of FIG. 2). In some embodiments, the result buffer is outputted to another database server (e.g., server 130 of FIG. 2).

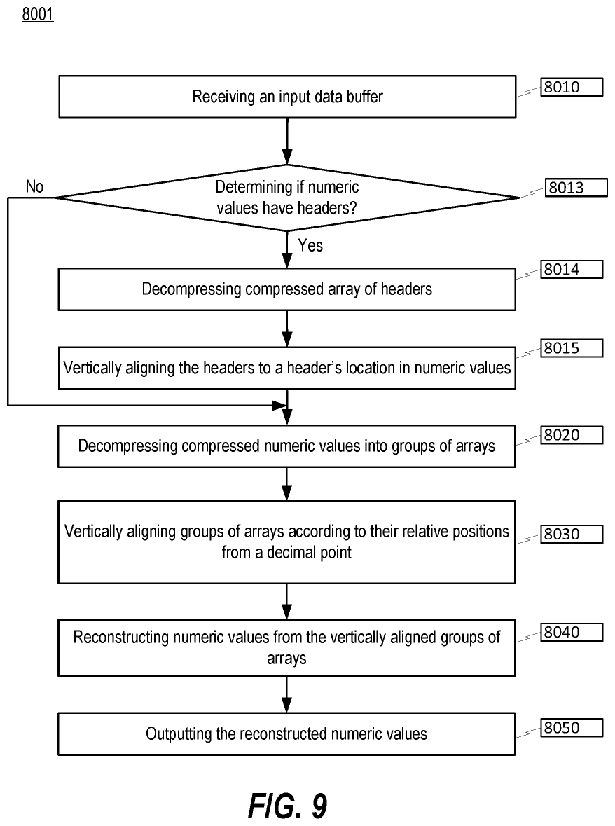

In some embodiments, the database can internally store a header for some or all of the numeric values. FIG. 9 illustrates a flowchart of an exemplary method for decompressing numeric data having headers based on vertical alignment in a database, according to some embodiments of the disclosure. On the basis of FIG. 8, method 8001 of FIG. 9 further comprises steps 8013, 8014, and 8015. It is appreciated that method 8001 of FIG. 5 may be performed by server 110 of FIG. 2.

In step 8013, it is determined whether the plurality of numeric values have headers. In some embodiments, the database system reads the input data buffer to determine if there is a compressed array of headers. If it is determined that the numeric values have headers, step 8014 and 8015 are executed. If it is determined that the numeric values do not have headers, step 8020 is executed.

In step 8014, the compressed array of headers are decompressed. In some embodiments, the headers are treated as an array of numeric values. As a result, headers are decompressed using the same decompression technique as the other numeric values. For example, as shown in FIG. 1(B), a numeric value may be represented as “2_byte_header 000D 0D80 1ED2 04D2.” The “2_byte_header” is extracted from the original numeric value.

In step 8015, headers are vertically aligned to a header's location in numeric values. In some embodiments, the header's location is at the beginning of each numeric values. For example, as shown in FIG. 1(B), a numeric value may be represented as “2_byte_header 000D 0D80 1ED2 04D2.” The “2_byte_header” is at the beginning of the numeric value.

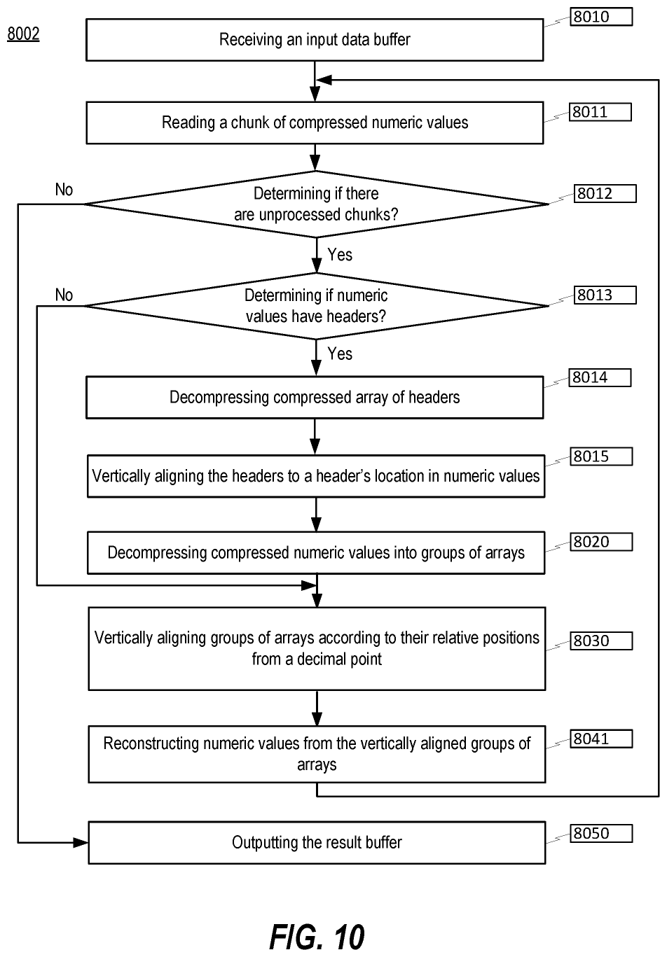

In some embodiments, the plurality of numeric values can be processed in units of chunks. In other words, the plurality of numeric values can be divided into a plurality of chunks, and each chunk of numeric values can be processed separately. FIG. 10 illustrates a flowchart of an exemplary method for decompressing numeric data arranged chunks based on vertical alignment in a database, according to some embodiments of the disclosure. On the basis of FIG. 9, method 8002 of FIG. 10 further comprises steps 8011, 8012, and 8041. It is appreciated that method 8002 of FIG. 10 may be performed by server 110 of FIG. 2.

In step 8011, a chunk of compressed numeric values is read from the input data buffer. In some embodiments, a chunk size parameter is used to keep track of a number of numeric values in a chunk. In some embodiments, the chunk size parameter can be read from the input data buffer. In some embodiments, the chunk size parameter has a default value of 512. For example, if the plurality of numeric values has 1224 numeric values in total, the plurality of numeric values is divided into three chunks. The first two chunks has 512 numeric values each, and the third chunk has the remaining 200 values.

In step 8012, it is determined whether there are chunks of numeric values that are not processed. If there are chunks that are not processed, a chunk of numeric values is sent to step 8013 for processing. If there are no more chunks to be processed, there would not be any chunk of numeric values being read in step 8011, and step 8050 is executed. As a result, the numeric values are processed in units of chunks.

In step 8041, numeric values are reconstructed from the vertically aligned groups of arrays. Unlike step 8040 of FIG. 8 and FIG. 9, the numeric values from step 8041 may not be the output of method 8002. Instead, step 8011 and 8012 are executed after step 8041 to read a next chunk of compressed numeric values and determine if there are chunks of numeric values that are not processed.

It is appreciated that the above described embodiments can be implemented by hardware, or software (program codes), or a combination of hardware and software. If implemented by software, it may be stored in the above-described computer-readable media. The software, when executed by the processor can perform the disclosed methods. The computing units and other functional units described in this disclosure can be implemented by hardware, or software, or a combination of hardware and software. It is understood that multiple ones of the above described modules/units may be combined as one module/unit, and each of the above described modules/units may be further divided into a plurality of sub-modules/sub-units.

The embodiments may further be described using the following clauses:

1. A method for compressing numeric data, the method comprising:

receiving a data set having a plurality of numeric values;

for each numeric value of the plurality of numeric values of the data set, dividing a numeric value into a plurality of arrays arranged according to a specific location of the numeric value, wherein the plurality of arrays include a first array and a second array;

grouping, across the plurality of numeric values, first arrays;

grouping, across the plurality of numeric values, second arrays; and

compressing the group of first arrays and the group of second arrays.

2. The method of clause 1, wherein the specific location is a decimal point of the numeric value.

3. The method of clause 1 or 2, wherein the database is a columnar database or a row-column hybrid storage database.

4. The method of clause 2 or 3, wherein for each numeric value of the plurality of numeric values of the data set, dividing a numeric value into a plurality of arrays arranged according to a specific location of the numeric value further comprises:

aligning arrays according to their relative positions from decimal points for grouping.

5. The method of any one of clauses 1-3, wherein for each numeric value of the plurality of numeric values of the data set, dividing a numeric value into a plurality of arrays arranged according to a specific location of the numeric value further comprises:

receiving a value for a size of an array;

grouping every X number of digits to a left of a decimal point in a numeric value into an array, wherein X is an integer and equals the value for the size of an array; and

grouping every Y number of digits to a right of a decimal point in a numeric value into an array, wherein Y is an integer and equals the value for the size of an array.

6. The method of clause 5, wherein the value for the size of an array is equal to 4 or 9.

7. The method of any one of clauses 1-6, wherein compressing the group of first arrays and the group of second arrays further comprises:

compressing the group of first arrays and the group of second arrays using integer compression techniques comprising run-length encoding, delta compression, bit-packing compression, or pFOR compression.

8. The method of any one of clauses 1-7, wherein receiving a data set having a plurality of numeric values further comprises:

receiving a plurality of numeric values that have headers;

extracting the headers from the plurality of numeric values;

creating a column comprising the headers; and

compressing the column.

9. The method of any one of clauses 1-8, further comprising:

arranging the plurality of numeric values into chunks; and

processing the plurality of numeric values in units of the chunks.

10. The method of clause 9, wherein arranging the plurality of numeric values into chunks further comprises:

receiving a value for a size of a chunk; and

grouping the plurality of numeric values into chunks having a size equal to the value for a size of a chunk.

11. A method for decompressing numeric data in a database, the method comprising:

receiving a data buffer comprising compressed numeric values;

decompressing the compressed numeric values into groups of arrays;

aligning the groups of arrays according to their relative positions from a specific location; and

reconstructing numeric values according to the aligned groups of arrays.

12. The method of clause 11, wherein the specific location is a decimal point.

13. The method of clause 11 or 12, wherein the database is a columnar database.

14. The method of any one of clauses 11-13, wherein decompressing the compressed numeric values into groups of arrays further comprising:

decompressing the compressed numeric values using decompression techniques corresponding to integer compression techniques comprising run-length encoding, delta compression, bit-packing compression, or pFOR compression.

15. The method of any one of clauses 11-14, wherein the relative position of each group of arrays is determined according to the group's location in the data buffer.

16. The method of any one of clauses 11-15, wherein reconstructing numeric values according to the aligned groups of arrays further comprising:

reconstructing the numeric values by combining the aligned arrays into a numeric value and adding a decimal point according to the relative positions of the aligned groups of arrays.

17. The method of any one of clauses 11-16, wherein receiving a data buffer comprising compressed numeric values further comprising:

determining if the data buffer comprises a compressed array of headers;

decompressing the compressed array of headers in response to a determination that the data buffer comprises a compressed array of headers; and

aligning the decompressed array of headers to a header's location in numeric values.

18. The method of any one of clauses 11-17, further comprising:

reading a chunk of compressed numeric values; and

processing numeric values in units of chunks.

19. A database system, comprising:

a memory storing a set of instructions; and

a processor configured to execute the set of instructions to cause the database system to:
receive a data set having a plurality of numeric values;
for each numeric value of the plurality of numeric values of the data set, divide a numeric value into a plurality of arrays arranged according to a specific location of the numeric value, wherein the plurality of arrays include a first array and a second array;
group, across the plurality of numeric values, first arrays;
group, across the plurality of numeric values, second arrays; and
compress the group of first arrays and the group of second arrays.

20. The database system of clause 19, wherein the specific location is a decimal point of the numeric value.

21. The database system of clause 19 or 20, wherein the database system comprises a columnar database or a row-column hybrid storage database.

22. The database system of any one of clauses 19-21, wherein the processor is further configured to cause the database system to:

align arrays according to their relative positions from decimal points for grouping.

23. The database system of any one of clauses 19-22, wherein the processor is further configured to cause the database system to:

receive a value for a size of an array;

group every X number of digits to a left of a decimal point in a numeric value into an array, wherein X is an integer and equals the value for the size of an array; and

group every Y number of digits to a right of a decimal point in a numeric value into an array, wherein Y is an integer and equals the value for the size of an array.

24. The database system of any one of clauses 19-23, wherein the processor is further configured to cause the database system to:

compress the group of first arrays and the group of second arrays using integer compression techniques comprising run-length encoding, delta compression, bit-packing compression, or pFOR compression.

25. The database system of any one of clauses 19-24, wherein the processor is further configured to cause the database system to:

receive a plurality of numeric values that have headers;

extract the headers from the plurality of numeric values;

create a column comprising the headers; and

compress the column.

26. The database system of any one of clauses 19-25, wherein the processor is further configured to cause the database system to:

arrange the plurality of numeric values into chunks; and

process the plurality of numeric values in units of the chunks.

27. A database system, comprising:

a memory storing a set of instructions; and

a processor configured to execute the set of instructions to cause the database system to:
receive a data buffer comprising compressed numeric values;
decompress the compressed numeric values into groups of arrays;
align the groups of arrays according to their relative positions from a specific location; and
reconstruct numeric values according to the aligned groups of arrays.

28. The database system of clause 27, wherein the specific location is a decimal point.

29. The database system of clause 27 or 28, further comprising a columnar database or a row-column hybrid storage database.

30. The database system of any one of clauses 27-29, wherein the processor is further configured to cause the database system to:

decompress the compressed numeric values using decompression techniques corresponding to integer compression techniques comprising run-length encoding, delta compression, bit-packing compression, or pFOR compression.

31. The database system of any one of clauses 27-30, wherein the relative position of each group of arrays is determined according to the group's location in the data buffer.

32. The database system of any one of clauses 27-31, wherein the processor is further configured to cause the database system to:

reconstruct the numeric values by combining the aligned arrays into a numeric value and adding a decimal point according to the relative positions of the aligned groups of arrays.

33. The database system of any one of clauses 27-32, wherein the processor is further configured to cause the database system to:

determine if the data buffer comprises a compressed array of headers;

decompress the compressed array of headers in response to a determination that the data buffer comprises a compressed array of headers; and

align the decompressed array of headers to a header's location in numeric values.

34. The database system of any one of clauses 27-33, wherein the processor is further configured to cause the database system to:

read a chunk of compressed numeric values; and

process numeric values in units of chunks.

35. A non-transitory computer readable medium that stores a set of instructions that is executable by one or more processors of an apparatus to cause the apparatus to initiate a method comprising:

receiving a data set having a plurality of numeric values;

for each numeric value of the plurality of numeric values of the data set, dividing a numeric value into a plurality of arrays arranged according to a specific location of the numeric value, wherein the plurality of arrays include a first array and a second array;

grouping, across the plurality of numeric values, first arrays;

grouping, across the plurality of numeric values, second arrays; and

compressing the group of first arrays and the group of second arrays.

36. The non-transitory computer readable medium of clause 35, wherein the specific location is a decimal point of the numeric value.

37. The non-transitory computer readable medium of clause 35 or 36, wherein the set of instructions that is executable by one or more processors of the apparatus to cause the apparatus to further perform:

aligning arrays according to their relative positions from decimal points for grouping.

38. The non-transitory computer readable medium of any one of clauses 35-37, wherein the set of instructions that is executable by one or more processors of the apparatus to cause the apparatus to further perform:

receiving a value for a size of an array;

grouping every X number of digits to a left of a decimal point in a numeric value into an array, wherein X is an integer and equals the value for the size of an array; and

grouping every Y number of digits to a right of a decimal point in a numeric value into an array, wherein Y is an integer and equals the value for the size of an array.

39. The non-transitory computer readable medium of any one of clauses 35-38, wherein the set of instructions that is executable by one or more processors of the apparatus to cause the apparatus to further perform:

receiving a plurality of numeric values that have headers;

extracting the headers from the plurality of numeric values;

creating a column comprising the headers; and

compressing the column.

40. The non-transitory computer readable medium of any one of clauses 35-39, wherein the set of instructions that is executable by one or more processors of the apparatus to cause the apparatus to further perform:

arranging the plurality of numeric values into chunks; and

processing the plurality of numeric values in units of the chunks.

41. A non-transitory computer readable medium that stores a set of instructions that is executable by one or more processors of an apparatus to cause the apparatus to initiate a method comprising:

receiving a data buffer comprising compressed numeric values;

decompressing the compressed numeric values into groups of arrays

aligning the groups of arrays according to their relative positions from a specific location; and

reconstructing numeric values according to the aligned groups of arrays.

42. The non-transitory computer readable medium of clause 41, wherein the specific location is a decimal point.

43. The non-transitory computer readable medium of clause 41 or 42, wherein the relative position of each group of arrays is determined according to the group's location in the data buffer.

44. The non-transitory computer readable medium of any one of clauses 41-43, wherein the set of instructions that is executable by one or more processors of the apparatus to cause the apparatus to further perform:

reconstructing the numeric values by combining the aligned arrays into a numeric value and adding a decimal point according to the relative positions of the aligned groups of arrays.

45. The non-transitory computer readable medium of any one of clauses 41-44, wherein the set of instructions that is executable by one or more processors of the apparatus to cause the apparatus to further perform:

determining if the data buffer comprises a compressed array of headers;

decompressing the compressed array of headers in response to a determination that the data buffer comprises a compressed array of headers; and

aligning the decompressed array of headers to a header's location in numeric values.

46. The non-transitory computer readable medium of any one of clauses 41-45, wherein the set of instructions that is executable by one or more processors of the apparatus to cause the apparatus to further perform:

reading a chunk of compressed numeric values; and

processing numeric values in units of chunks.

Unless specifically stated otherwise, the term “or” encompasses all possible combinations, except where infeasible. For example, if it is stated that a component may include A or B, then, unless specifically stated otherwise or infeasible, the component may include A, or B, or A and B. As a second example, if it is stated that a component may include A, B, or C, then, unless specifically stated otherwise or infeasible, the component may include A, or B, or C, or A and B, or A and C, or B and C, or A and B and C.

In the foregoing specification, embodiments have been described with reference to numerous specific details that can vary from implementation to implementation. Certain adaptations and modifications of the described embodiments can be made. Other embodiments can be apparent to those skilled in the art from consideration of the specification and practice of the invention disclosed herein. It is intended that the specification and examples be considered as exemplary only, with a true scope and spirit of the invention being indicated by the following claims. It is also intended that the sequence of steps shown in figures are only for illustrative purposes and are not intended to be limited to any particular sequence of steps. As such, those skilled in the art can appreciate that these steps can be performed in a different order while implementing the same method. In the drawings and specification, there have been disclosed exemplary embodiments. However, many variations and modifications can be made to these embodiments. Accordingly, although specific terms are employed, they are used in a generic and descriptive sense only and not for purposes of limitation, the scope of the embodiments being defined by the following claims.

What is claimed is:

1. A method for compressing numeric data, the method comprising:
receiving a data set having a plurality of numeric values;
for each numeric value of the plurality of numeric values of the data set, dividing a numeric value into a plurality of arrays arranged according to a specific location of the numeric value, wherein the plurality of arrays include a first array and a second array;
grouping, across the plurality of numeric values, first arrays;
grouping, across the plurality of numeric values, second arrays; and
compressing the group of first arrays and the group of second arrays.

2. The method of claim 1, wherein the specific location is a decimal point of the numeric value.

3. The method of claim 1, wherein the database is a columnar database or a row-column hybrid storage database.

4. The method of claim 2, wherein for each numeric value of the plurality of numeric values of the data set, dividing a numeric value into a plurality of arrays arranged according to a specific location of the numeric value further comprises:
aligning arrays according to their relative positions from decimal points for grouping.

5. The method of claim 1, wherein for each numeric value of the plurality of numeric values of the data set, dividing a numeric value into a plurality of arrays arranged according to a specific location of the numeric value further comprises:
receiving a value for a size of an array;
grouping every X number of digits to a left of a decimal point in a numeric value into an array, wherein X is an integer and equals the value for the size of an array; and
grouping every Y number of digits to a right of a decimal point in a numeric value into an array, wherein Y is an integer and equals the value for the size of an array.

6. The method of claim 5, wherein the value for the size of an array is equal to 4 or 9.

7. The method of claim 1, wherein compressing the group of first arrays and the group of second arrays further comprises:
compressing the group of first arrays and the group of second arrays using integer compression techniques comprising run-length encoding, delta compression, bit-packing compression, or pFOR compression.

8. The method of claim 1, wherein receiving a data set having a plurality of numeric values further comprises:
receiving a plurality of numeric values that have headers;
extracting the headers from the plurality of numeric values;
creating a column comprising the headers; and
compressing the column.

9. The method of claim 1, further comprising:
arranging the plurality of numeric values into chunks; and
processing the plurality of numeric values in units of the chunks.

10. The method of claim 9, wherein arranging the plurality of numeric values into chunks further comprises:
receiving a value for a size of a chunk; and
grouping the plurality of numeric values into chunks having a size equal to the value for a size of a chunk.

11. A database system, comprising:
a memory storing a set of instructions; and
a processor configured to execute the set of instructions to cause the database system to:
receive a data set having a plurality of numeric values;
for each numeric value of the plurality of numeric values of the data set, divide a numeric value into a plurality of arrays arranged according to a specific location of the numeric value, wherein the plurality of arrays include a first array and a second array;
group, across the plurality of numeric values, first arrays;
group, across the plurality of numeric values, second arrays; and
compress the group of first arrays and the group of second arrays.

12. The database system of claim 11, wherein the specific location is a decimal point of the numeric value.

13. The database system of claim 11, wherein the database system comprises a columnar database or a row-column hybrid storage database.

14. The database system of claim 11, wherein the processor is further configured to cause the database system to:
align arrays according to their relative positions from decimal points for grouping.

15. The database system of claim 11, wherein the processor is further configured to cause the database system to:
receive a value for a size of an array;
group every X number of digits to a left of a decimal point in a numeric value into an array, wherein X is an integer and equals the value for the size of an array; and
group every Y number of digits to a right of a decimal point in a numeric value into an array, wherein Y is an integer and equals the value for the size of an array.

16. The database system of claim 11, wherein the processor is further configured to cause the database system to:
compress the group of first arrays and the group of second arrays using integer compression techniques comprising run-length encoding, delta compression, bit-packing compression, or pFOR compression.

17. The database system of claim 11, wherein the processor is further configured to cause the database system to:
receive a plurality of numeric values that have headers;
extract the headers from the plurality of numeric values;
create a column comprising the headers; and
compress the column.

18. The database system of claim 11, wherein the processor is further configured to cause the database system to:
arrange the plurality of numeric values into chunks; and
process the plurality of numeric values in units of the chunks.

19. A non-transitory computer readable medium that stores a set of instructions that is executable by one or more processors of an apparatus to cause the apparatus to initiate a method comprising:
receiving a data set having a plurality of numeric values;
for each numeric value of the plurality of numeric values of the data set, dividing a numeric value into a plurality of arrays arranged according to a specific location of the numeric value, wherein the plurality of arrays include a first array and a second array;
grouping, across the plurality of numeric values, first arrays;
grouping, across the plurality of numeric values, second arrays; and
compressing the group of first arrays and the group of second arrays.

20. The non-transitory computer readable medium of claim 19, wherein the specific location is a decimal point of the numeric value.

21. The non-transitory computer readable medium of claim 19, wherein the set of instructions that is executable by one or more processors of the apparatus to cause the apparatus to further perform:
aligning arrays according to their relative positions from decimal points for grouping.

22. The non-transitory computer readable medium of claim 19, wherein the set of instructions that is executable by one or more processors of the apparatus to cause the apparatus to further perform:
receiving a value for a size of an array;
grouping every X number of digits to a left of a decimal point in a numeric value into an array, wherein X is an integer and equals the value for the size of an array; and
grouping every Y number of digits to a right of a decimal point in a numeric value into an array, wherein Y is an integer and equals the value for the size of an array.

23. The non-transitory computer readable medium of claim 19, wherein the set of instructions that is executable by one or more processors of the apparatus to cause the apparatus to further perform:
receiving a plurality of numeric values that have headers;
extracting the headers from the plurality of numeric values;
creating a column comprising the headers; and
compressing the column.

24. The non-transitory computer readable medium of claim 19, wherein the set of instructions that is executable by one or more processors of the apparatus to cause the apparatus to further perform:
arranging the plurality of numeric values into chunks; and
processing the plurality of numeric values in units of the chunks.
